(19) United States
(12) Patent Application Publication
(10) Pub. No.: US 2021/0065927 A1
(43) Pub. Date: Mar. 4, 2021

(54) TRANSPARENT ELECTRICALLY CONDUCTIVE FILM, PRODUCING METHOD OF TRANSPARENT ELECTRICALLY CONDUCTIVE FILM, AND INTERMEDIATE

(71) Applicant: NITTO DENKO CORPORATION, Osaka (JP)

(72) Inventors: Tomohiro Takeyasu, Ibaraki-shi (JP); Hideki Nobesawa, Ibaraki-shi (JP)

(73) Assignee: NITTO DENKO CORPORATION, Osaka (JP)

(21) Appl. No.: 17/008,823

(22) Filed: Sep. 1, 2020

(30) Foreign Application Priority Data
Sep. 2, 2019 (JP) 2019-159537

(51) Int. Cl. H01B 5/14; G06F 3/041

(52) U.S. Cl. CPC H01B 5/14; H01L 27/323; G06F 3/041

(57) ABSTRACT

A transparent electrically conductive film 1 sequentially includes a transparent substrate 2 and an electrically conductive layer 3 toward one side in a thickness direction. The electrically conductive layer 3 includes a visible region 10 and a frame region 11 disposed in a peripheral edge portion of the visible region 10. The visible region 10 includes a transparent electrically conductive layer 4. The frame region 11 includes a conductive layer 5, the transparent electrically conductive layer 4, and an electrically conductive adhesive layer 6 disposed therebetween for achieving adhesion of the conductive layer 5 to the transparent electrically conductive layer 4. The transparent electrically conductive layer 4 includes a metal nanowire.

### REFERENCE TO RELATED APPLICATION

The present application claims priority from Japanese Patent Application No. 2019-159537 filed on Sep. 2, 2019, the contents of which are hereby incorporated by reference into this application.

### TECHNICAL FIELD

The present invention relates to a transparent electrically conductive film, a method for producing a transparent electrically conductive film, and an intermediate, to be specific, to a transparent electrically conductive film preferably used for optical uses, a method for producing a transparent electrically conductive film, and an intermediate used for the method for producing a transparent electrically conductive film.

### BACKGROUND ART

A transparent electrically conductive film that forms a transparent electrically conductive layer including a metal nanowire into a desired electrode pattern has been conventionally used for optical uses such as touch panels.

As such a transparent electrically conductive film, a touch input sensor that includes a transparent board, a first photosensitive resin layer, a transparent electrically conductive film layer including a silver nanowire, a metal thin film layer, and a second photosensitive resin layer has been proposed (ref: for example, Patent Document 1).

### PRIOR ART DOCUMENT

### Patent Document

[Patent Document 1] Japanese Unexamined Patent Publication No. 2017-27231

### SUMMARY OF THE INVENTION

### Problems to be Solved by the Invention

Meanwhile, in the touch input sensor of Patent Document 1, there is a disadvantage that adhesive properties of the metal thin film layer with the transparent electrically conductive layer including the metal nanowire are low, so that the transparent electrically conductive layer is peeled.

The present invention provides a transparent electrically conductive film having excellent adhesive properties of a conductive layer with a transparent electrically conductive layer, a method for producing a transparent electrically conductive film, and an intermediate used for the method for producing a transparent electrically conductive film.

### Solution to the Problems

The present invention [1] includes a transparent electrically conductive film sequentially including a transparent substrate and an electrically conductive layer toward one side in a thickness direction, wherein the electrically conductive layer includes a visible region and a frame region disposed in a peripheral edge portion of the visible region; the visible region includes a transparent electrically conductive layer; the frame region includes a conductive layer, the transparent electrically conductive layer, and an electrically conductive adhesive layer disposed therebetween for achieving adhesion of the conductive layer to the transparent electrically conductive layer; and the transparent electrically conductive layer includes a metal nanowire.

The present invention [2] includes the transparent electrically conductive film described in the above-described [1], wherein the frame region sequentially includes the conductive layer, the electrically conductive adhesive layer, and the transparent electrically conductive layer toward one side in the thickness direction.

The present invention [3] includes the transparent electrically conductive film described in the above-described [1] or [2], wherein the electrically conductive layer is disposed on both sides of the transparent substrate.

The present invention [4] includes the transparent electrically conductive film described in any one of the above-described [1] to [3], wherein the metal nanowire is a silver nanowire.

The present invention [5] includes the transparent electrically conductive film described in any one of the above-described [1] to [4], wherein the conductive layer is a copper layer.

The present invention [6] includes the transparent electrically conductive film described in any one of the above-described [1] to [5], wherein the electrically conductive adhesive layer contains one or more selected from the group consisting of chromium, nickel, silicon oxide, and aluminum-doped zinc oxide.

The present invention [7] includes the transparent electrically conductive film described in any one of the above-described [1] to [6] for photo resist or wet etching.

The present invention [8] includes a method for producing a transparent electrically conductive film including a first step of preparing a transparent substrate and a second step of disposing an electrically conductive layer including a visible region and a frame region disposed in a peripheral edge portion of the visible region on the transparent substrate, wherein in the second step, a transparent electrically conductive layer is disposed in the visible region, and a conductive layer, the transparent electrically conductive layer, and an electrically conductive adhesive layer disposed therebetween for achieving adhesion of the conductive layer to the transparent electrically conductive layer are disposed in the frame region; and the transparent electrically conductive layer includes a metal nanowire.

The present invention [9] includes an intermediate used for the method for producing a transparent electrically conductive film described in the above-described [8] sequentially including the transparent substrate, the conductive layer, and the electrically conductive adhesive layer toward one side in a thickness direction, or the transparent substrate, the transparent electrically conductive layer, and the electrically conductive adhesive layer toward one side in the thickness direction.

### Effect of Invention

In the transparent electrically conductive film of the present invention, a frame region includes a conductive layer, a transparent electrically conductive layer, and an electrically conductive adhesive layer disposed therebetween for achieving adhesion of the conductive layer to the transparent electrically conductive layer.

Thus, adhesive properties between the conductive layer and the transparent electrically conductive layer are excellent.

The method for producing a transparent electrically conductive film of the present invention includes a step of disposing the conductive layer, the transparent electrically conductive layer, and the electrically conductive adhesive layer disposed therebetween for achieving the adhesion of the conductive layer to the transparent electrically conductive layer in the frame region.

Thus, the transparent electrically conductive film having excellent adhesive properties between the conductive layer and the transparent electrically conductive layer can be obtained.

The intermediate of the present invention is used for the method for producing a transparent electrically conductive film of the present invention. Thus, according to the intermediate, the transparent electrically conductive film having excellent adhesive properties between the conductive layer and the transparent electrically conductive layer can be obtained.

### BRIEF DESCRIPTION OF THE DRAWINGS

FIG. 1 shows a cross-sectional view of one embodiment of a transparent electrically conductive film of the present invention.

FIGS. 2A to 2E show one embodiment of a method for producing a transparent electrically conductive film of the present invention:

FIG. 2A illustrating a first step of preparing a transparent substrate,

FIG. 2B illustrating a step of disposing a conductive layer on a one-side surface in a thickness direction of the transparent substrate in a second step,

FIG. 2C illustrating a step of disposing an electrically conductive adhesive layer on the one-side surface in the thickness direction of the conductive layer in the second step,

FIG. 2D illustrating a step of forming a visible region and a frame region by forming the conductive layer and the electrically conductive adhesive layer into a pattern in the second step, and

FIG. 2E illustrating a step of disposing a transparent electrically conductive layer on the one-side surface in the thickness direction of the visible region and the one-side surface in the thickness direction of the frame region in the second step.

FIG. 3 shows a cross-sectional view of a modified example (case of disposing an electrically conductive layer on both sides of a transparent substrate) of the transparent electrically conductive film shown in FIG. 1.

FIG. 4 shows a cross-sectional view of a modified example (case of including a hard coat layer) of the transparent electrically conductive film shown in FIG. 1.

### EMBODIMENT OF THE INVENTION

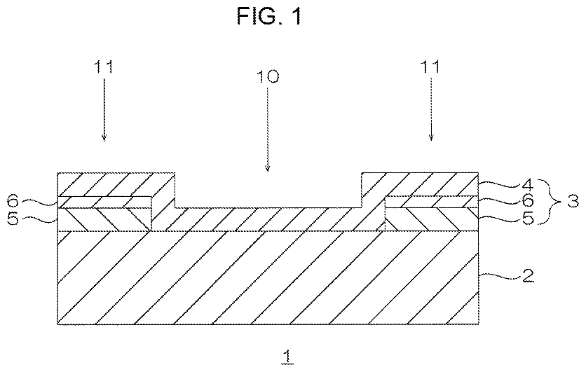

One embodiment of a transparent electrically conductive film of the present invention is described with reference to FIG. 1.

In FIG. 1, the up-down direction on the plane of the sheet is an up-down direction (thickness direction), the upper side on the plane of the sheet is an upper side (one side in the thickness direction), and the lower side on the plane of the sheet is a lower side (the other side in the thickness direction). The right-left direction and the depth direction on the plane of the sheet are a plane direction perpendicular to the up-down direction. To be specific, directions are in conformity with direction arrows of each view.

1. Transparent Electrically Conductive Film

A transparent electrically conductive film 1 has a film shape (including a sheet shape) having a predetermined thickness, extends in the plane direction perpendicular to the thickness direction, and has a flat upper surface and a flat lower surface. The transparent electrically conductive film 1 is, for example, one component of a substrate for touch panels and electromagnetic shield provided in an image display device, that is, not the image display device. That is, the transparent electrically conductive film 1 is a component for fabricating the image display device or the like, does not include an image display element such as OLED module, and is an industrially available device whose component alone is circulated.

To be specific, as shown in FIG. 1, the transparent electrically conductive film 1 sequentially includes a transparent substrate 2 and an electrically conductive layer 3 toward one side in the thickness direction. To be more specific, the transparent electrically conductive film 1 includes the transparent substrate 2 and the electrically conductive layer 3 that is disposed on the upper surface (one-side surface in the thickness direction) of the transparent substrate 2.

The transparent electrically conductive film 1 has a thickness of, for example, 200 μm or less, preferably 150 μm or less, and for example, 20 μm or more, preferably 30 μm or more.

2. Transparent Substrate

The transparent substrate 2 is a transparent substrate for ensuring mechanical strength of the transparent electrically conductive film 1.

The transparent substrate 2 has a film shape. The transparent substrate 2 is disposed on the entire lower surface of the electrically conductive layer 3 so as to be in contact with the lower surface of the electrically conductive layer 3.

The transparent substrate 2 is, for example, a polymer film having transparency.

Examples of a material for the transparent substrate 2 include olefin resins such as polyethylene, polypropylene, and cycloolefin polymer; polyester resins such as polyethylene terephthalate (PET), polybutylene terephthalate, and polyethylene naphthalate; (meth)acrylic resins (acrylic resins and/or methacryl resins) such as polymethacrylate; polycarbonate resin; polyether sulfone resin; polyarylate resin; melamine resin; polyamide resin; polyimide resin; cellulose resin; and polystyrene resin.

These materials for the transparent substrate 2 can be used alone or in combination of two or more.

As the material for the transparent substrate 2, preferably, a cycloolefin polymer is used. That is, the transparent substrate 2 is preferably a cycloolefin film formed from a cycloolefin polymer.

The cycloolefin polymer is a polymer obtained by polymerizing a cycloolefin monomer, and having an alicyclic structure in a repeating unit of a main chain thereof. The cycloolefin resin is preferably a noncrystalline cycloolefin resin.

Examples of the cycloolefin polymer include cycloolefin homopolymer consisting of a cycloolefin monomer, and cycloolefin copolymer consisting of a copolymer of a cycloolefin monomer with an olefin such as ethylene.

Examples of the cycloolefin monomer include polycyclic olefins such as norbornene, methyl norbornene, dimethyl norbornene, ethylidene norbornene, butyl norbornene, dicyclopentadiene, dihydrodicyclopentadiene, tetracyclododecene, and tricyclopentadiene and monocyclic olefins such as cyclobutene, cyclopentene, cyclooctadiene, and cyclooctatriene. Preferably, a polycyclic olefin is used. These cycloolefins can be used alone or in combination of two or more.

In view of mechanical strength or the like, the transparent substrate 2 has a thickness of, for example, 2 μm or more, preferably 15 μm or more, and for example, 300 μm or less, preferably 150 μm or less, more preferably, in view of reduction in thickness and flexibility, below 50 μm. The thickness of the transparent substrate 2 can be, for example, measured by using a micro gauge-type thickness meter.

3. Electrically Conductive Layer

The electrically conductive layer 3 is a layer that imparts electrical conductivity to the transparent electrically conductive film 1.

The electrically conductive layer 3 is disposed on the entire upper surface of the transparent substrate 2 so as to be in contact with the upper surface (one-side surface in the thickness direction) of the transparent substrate 2.

The electrically conductive layer 3 includes a visible region 10, and a frame region 11 that is disposed in a peripheral edge portion of the visible region 10.

The visible region 10 is, for example, a touch input region of a touch panel, and includes a transparent electrically conductive layer 4.

The frame region 11 is a region for forming a wiring pattern (not shown), and includes a conductive layer 5, the transparent electrically conductive layer 4, and an electrically conductive adhesive layer 6 that is disposed therebetween.

To be specific, the frame region 11 sequentially includes the conductive layer 5, the electrically conductive adhesive layer 6, and the transparent electrically conductive layer 4 toward one side in the thickness direction, or sequentially includes the transparent electrically conductive layer 4, the electrically conductive adhesive layer 6, and the conductive layer 5 toward one side in the thickness direction. Preferably, in view of narrow frame, the frame region 11 sequentially includes the conductive layer 5, the electrically conductive adhesive layer 6, and the transparent electrically conductive layer 4 toward one side in the thickness direction.

In the following, a case where the frame region 11 sequentially includes the conductive layer 5, the electrically conductive adhesive layer 6, and the transparent electrically conductive layer 4 toward one side in the thickness direction is described in detail.

In this case, the transparent electrically conductive film 1 includes the transparent substrate 2, and the transparent electrically conductive layer 4 that is disposed on the upper surface (one-side surface in the thickness direction) of the transparent substrate 2 in the visible region 10.

The transparent electrically conductive film 1 includes the transparent substrate 2, the conductive layer 5 that is disposed on the upper surface (one-side surface in the thickness direction) of the transparent substrate 2, the electrically conductive adhesive layer 6 that is disposed on the upper surface (one-side surface in the thickness direction) of the conductive layer 5, and the transparent electrically conductive layer 4 that is disposed on the upper surface (one-side surface in the thickness direction) of the electrically conductive adhesive layer 6 in the frame region 11.

The transparent electrically conductive layer 4 is the uppermost layer in the transparent electrically conductive film 1, and is disposed across the visible region 10 and the frame region 11 so as to be continuously disposed on the upper surface (one-side surface in the thickness direction) of the transparent substrate 2 in the visible region 10, the upper surface (one-side surface in the thickness direction) of the electrically conductive adhesive layer 6 in the frame region 11, and entirely on the inner-side surfaces of the conductive layer 5 and the electrically conductive adhesive layer 6 on the border between the visible region 10 and the frame region 11.

4. Transparent Electrically Conductive Layer

The transparent electrically conductive layer 4 is a transparent layer that develops excellent electrical conductivity.

The transparent electrically conductive layer 4 is formed from a transparent electrically conductive composition.

The transparent electrically conductive composition includes a metal nanowire and a binder resin. That is, the transparent electrically conductive layer 4 includes the metal nanowire.

When the transparent electrically conductive layer 4 includes the metal nanowire, the metal nanowire has a mesh shape, so that an excellent electricity conduction path can be formed with a small amount of metal nanowire, and resistivity can be reduced. Also, by having a mesh-shaped metal nanowire, an opening portion can be formed in a gap of the mesh, and light transmittance can be improved.

The metal nanowire is an electrically conductive material having, for example, an outer size of about 10 nm as an average size, and having a needle shape or filiform shape.

Examples of a metal constituting the metal nanowire include copper, silver, gold, platinum, palladium, nickel, tin, cobalt, rhodium, iridium, iron, ruthenium, osmium, manganese, molybdenum, tungsten, niobium, tantalum, titanium, bismuth, antimony, lead, or alloy thereof. Preferably, silver is used.

That is, the metal nanowire is preferably a silver nanowire.

When the metal nanowire is the silver nanowire, the resistivity of the transparent electrically conductive layer 4 can be reduced.

The binder resin is not particularly limited, and examples thereof include acrylic resin, epoxy resin, amide resin, alkyd resin, phenol resin, urethane resin, and cellulose derivative.

The transparent electrically conductive composition is obtained by mixing the binder resin with the metal nanowire.

A mixing ratio of the binder resin with respect to the transparent electrically conductive composition is, for example, 75 mass % or more.

A mixing ratio of the metal nanowire with respect to the transparent electrically conductive composition is, for example, 0.1 mass % or more.

The transparent electrically conductive composition can be diluted with a solvent as needed.

In view of corrosion prevention or the like, a known additive such as oxidation inhibitor and ultraviolet absorber can be blended into the transparent electrically conductive composition as needed.

The transparent electrically conductive layer 4 is formed by a method to be described later.

The transparent electrically conductive layer 4 has a thickness of, for example, 10 nm or more, preferably 30 nm or more, more preferably 40 nm or more, and for example, 80 nm or less.

The thickness of the transparent electrically conductive layer 4 can be, for example, measured by observing a cross section of the transparent electrically conductive film 1 by using a transmission electron microscope.

A surface resistance value of the transparent electrically conductive layer 4 is, for example, 70Ω/□ or less, preferably 30Ω/□ or less.

When the surface resistance value of the transparent electrically conductive layer 4 is the above-described upper limit or less, excellent electric properties can be developed in using the transparent electrically conductive layer 4 as an electrode by being subjected to patterning.

A lower limit of the surface resistance value of the transparent electrically conductive layer 4 is not particularly limited. The surface resistance value of the transparent electrically conductive layer 4 is, for example, usually above 0Ω/□, and 1Ω/□ or more.

The surface resistance value can be measured in conformity with JIS K7194 by a four-terminal method.

5. Conductive Layer

The conductive layer 5 is a layer for being connected to a wiring pattern (not shown) in the frame region 11.

The conductive layer 5 has a frame shape when viewed from the top.

Examples of a material for the conductive layer 5 include metals such as copper, silver, gold, nickel, or alloy thereof.

These materials for the conductive layer 5 can be used alone or in combination of two or more.

As the material for the conductive layer 5, in view of electrical conductivity or the like, preferably, copper is used.

That is, the conductive layer 5 is preferably a copper layer.

When the conductive layer 5 is a material that is easily oxidized such as copper, the surface of the conductive layer 5 may be oxidized. To be specific, when the conductive layer 5 is a copper layer, the conductive layer 5 may be a copper layer that contains copper oxide on a part or the whole of the surface thereof.

The conductive layer 5 is formed by a method to be described later.

The conductive layer 5 has a thickness of, for example, 40 nm or more, preferably 100 nm or more, and for example, 400 nm or less.

The thickness of the conductive layer 5 can be, for example, measured by observing a cross section of the transparent electrically conductive film 1 by using the transmission electron microscope.

6. Electrically Conductive Adhesive Layer

The electrically conductive adhesive layer 6 is a layer for achieving adhesion of the conductive layer 5 to the transparent electrically conductive layer 4.

The electrically conductive adhesive layer 6 has a frame shape when viewed from the top.

Examples of a material for the electrically conductive adhesive layer 6 include chromium, nickel, silicon oxide (SiOₓ, (0<x<2)), copper-nickel-titanium (Cu—Ni—Ti) alloy, and aluminum-doped zinc oxide (AZO).

These materials for the electrically conductive adhesive layer 6 can be used alone or in combination of two or more.

As the material for the electrically conductive adhesive layer 6, in view of adhesive properties of the transparent electrically conductive layer 4 with the conductive layer 5, preferably, chromium, copper-nickel-titanium (Cu—Ni—Ti) alloy, silicon oxide (SiOₓ), and aluminum-doped zinc oxide (AZO) are used, more preferably, chromium, silicon oxide (SiOₓ), and aluminum-doped zinc oxide (AZO) are used, further more preferably, chromium and silicon oxide (SiOₓ) are used, particularly preferably, silicon oxide (SiOₓ) is used.

That is, in view of adhesive properties of the transparent electrically conductive layer 4 with the conductive layer 5, the electrically conductive adhesive layer 6 preferably contains one or more selected from the group consisting of chromium (preferably, chromium contained in the copper-nickel-titanium (Cu—Ni—Ti) alloy), nickel, silicon oxide, and aluminum-doped zinc oxide.

The electrically conductive adhesive layer 6 is formed by a method to be described later.

The electrically conductive adhesive layer 6 has a thickness of, for example, 1 nm or more, and for example, 10 nm or less.

Among all, when the material for the electrically conductive adhesive layer 6 is any one of chromium, silicon oxide (SiOₓ), and aluminum-doped zinc oxide (AZO), the electrically conductive adhesive layer 6 has a thickness of, for example, 1 nm or more, and for example, 10 nm or less, preferably 5 nm or less, more preferably 3 nm or less.

When the material for the electrically conductive adhesive layer 6 is any one of nickel and copper-nickel-titanium (Cu—Ni—Ti) alloy, the electrically conductive adhesive layer 6 has a thickness of, for example, 1 nm or more, preferably 5 nm or more, and for example, 10 nm or less.

7. Method for Producing Transparent Electrically Conductive Film

Next, a method for producing the transparent electrically conductive film 1 is described.

The method for producing the transparent electrically conductive film 1 includes a first step of preparing the transparent substrate 2, and a second step of disposing the electrically conductive layer 3 on the transparent substrate 2. In the producing method, each layer is, for example, sequentially disposed by a roll-to-roll method.

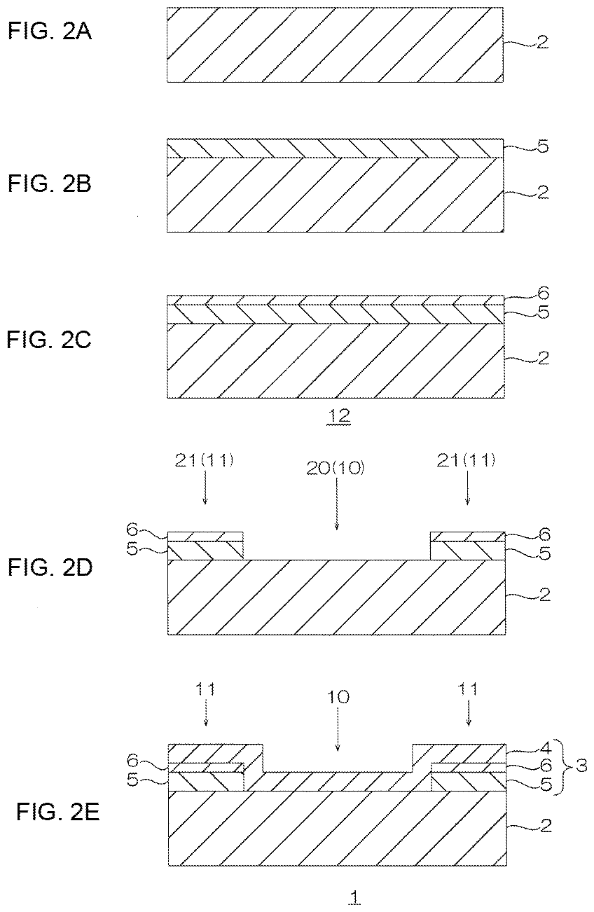

In the first step, as shown in FIG. 2A, the transparent substrate 2 is prepared.

In the second step, the electrically conductive layer 3 is disposed on the transparent substrate 2. To be specific, the electrically conductive layer 3 is disposed on the one-side surface in the thickness direction of the transparent substrate 2.

To be more specific, in the second step, the transparent electrically conductive layer 4 is disposed in the visible region 10, and the conductive layer 5, the electrically conductive adhesive layer 6, and the transparent electrically conductive layer 4 are sequentially disposed toward one side in the thickness direction in the frame region 11.

In the following, the details are specifically described.

In the second step, first, as shown in FIG. 2B, the conductive layer 5 is disposed on the entire one-side surface in the thickness direction of the transparent substrate 2.

Examples of a method for disposing the conductive layer 5 on the entire one-side surface in the thickness direction of the transparent substrate 2 include vacuum vapor deposition method, sputtering method, laminate method, plating method, and ion plating method. Preferably, a sputtering method is used.

In the sputtering method, a target and the transparent substrate 2 are disposed to face each other in a vacuum chamber, and a voltage is applied thereto from a power source, while gas is supplied. Thus, a gas ion is accelerated to be applied to the target, so that a target material is sprung out from the surface of the target to be laminated on the surface of the transparent substrate 2.

An example of the gas includes an inert gas such as Ar. Also, a reactive gas such as oxygen gas can be used in combination as needed. When the reactive gas is used in combination, a flow ratio (sccm) of the reactive gas is not particularly limited, and is, for example, 0.1 flow % or more and 5 flow % or less with respect to a total flow ratio of the sputtering gas and the reactive gas.

An atmospheric pressure during the sputtering is, for example, 0.1 Pa or more, and for example, 1.0 Pa or less, preferably 0.7 Pa or less.

The power source may be, for example, any one of DC power source, AC power source, MF power source, and RF power source, or these may be used in combination.

In this manner, the conductive layer 5 is disposed on the entire one-side surface in the thickness direction of the transparent substrate 2.

Next, in the second step, as shown in FIG. 2C, the electrically conductive adhesive layer 6 is disposed on the entire one-side surface in the thickness direction of the conductive layer 5.

Examples of a method for disposing the electrically conductive adhesive layer 6 on the entire one-side surface in the thickness direction of the conductive layer 5 include sputtering method, plating method, and vacuum vapor deposition method. Preferably, a sputtering method is used.

Conditions of the sputtering (flow ratio of the reactive gas and atmospheric pressure during the sputtering) are the same as those of the sputtering in the conductive layer 5 described above.

In this manner, the electrically conductive adhesive layer 6 is disposed on the entire one-side surface in the thickness direction of the conductive layer 5. Also, an intermediate 12 (describe later) sequentially including the transparent substrate 2, the conductive layer 5, and the electrically conductive adhesive layer 6 toward one side in the thickness direction is obtained.

Next, in the second step, as shown in FIG. 2D, the conductive layer 5 and the electrically conductive adhesive layer 6 are formed into a pattern, so that the visible region 10 and the frame region 11 are formed (defined).

An example of a method for forming the conductive layer 5 and the electrically conductive adhesive layer 6 into a pattern includes a known etching method.

To be specific, the conductive layer 5 and the electrically conductive adhesive layer 6 are formed into a pattern in a frame shape when viewed from the top. In other words, the conductive layer 5 and the electrically conductive adhesive layer 6 in a central portion 20 when viewed from the top of the conductive layer 5 and the electrically conductive adhesive layer 6 are removed, and a pattern is formed so as to leave the conductive layer 5 and the electrically conductive adhesive layer 6 in a peripheral edge portion 21 of the central portion 20.

In this manner, the above-described central portion 20 is defined as the visible region 10, and the peripheral edge portion 21 is defined as the frame region 11.

That is, a region where the conductive layer 5 and the electrically conductive adhesive layer 6 are disposed is the frame region 11, and a region where the conductive layer 5 and the electrically conductive adhesive layer 6 are not disposed is the visible region 10.

Next, in the second step, as shown in FIG. 2E, the transparent electrically conductive layer 4 is disposed on the one-side surface in the thickness direction of the visible region 10, the one-side surface in the thickness direction of the frame region 11, and the inner-side surfaces of the conductive layer 5 and the electrically conductive adhesive layer 6 on the border between the visible region 10 and the frame region 11.

To be specific, the transparent electrically conductive layer 4 is disposed across the visible region 10 and the frame region 11. To be more specific, the transparent electrically conductive layer 4 is disposed on the one-side surface in the thickness direction of the transparent substrate 2 in the visible region 10, disposed on the one-side surface in the thickness direction of the electrically conductive adhesive layer 6 in the frame region 11, and disposed on the inner-side surfaces of the conductive layer 5 and the electrically conductive adhesive layer 6 on the border between the visible region 10 and the frame region 11. Then, the transparent electrically conductive layer 4 in the visible region 10, the transparent electrically conductive layer 4 in the frame region 11, and the transparent electrically conductive layer 4 on the border between the visible region 10 and the frame region 11 are formed continuously.

To dispose the transparent electrically conductive layer 4, a diluted solution of the transparent electrically conductive composition is applied to the one-side surface in the thickness direction of the visible region 10 (one-side surface in the thickness direction of the transparent substrate 2), the one-side surface in the thickness direction of the frame region 11 (one-side surface in the thickness direction of the electrically conductive adhesive layer 6), and the inner-side surfaces of the conductive layer 5 and the electrically conductive adhesive layer 6 on the border between the visible region 10 and the frame region 11 to be then dried.

In this manner, the transparent electrically conductive layer 4 is disposed on the one-side surface in the thickness direction of the visible region 10, the one-side surface in the thickness direction of the frame region 11, and the inner-side surfaces of the conductive layer 5 and the electrically conductive adhesive layer 6 on the border between the visible region 10 and the frame region 11.

As described above, in the second step, the transparent electrically conductive layer 4 is disposed in the visible region 10, and the conductive layer 5, the electrically conductive adhesive layer 6, and the transparent electrically conductive layer 4 are sequentially disposed toward one side in the thickness direction in the frame region 11.

In this manner, the transparent electrically conductive film 1 sequentially including the transparent substrate 2 and the electrically conductive layer 3 toward one side in the thickness direction is obtained.

The transparent electrically conductive layer 4 of the transparent electrically conductive film 1 can be, for example, formed into a pattern by a known patterning method such as photo resist and wet etching.

Preferably, the transparent electrically conductive layer 4 is formed into a pattern by photo resist or wet etching.

That is, the transparent electrically conductive film 1 is preferably used for photo resist or wet etching.

8. Function and Effect

In the transparent electrically conductive film 1, the frame region 11 sequentially includes the conductive layer 5, the electrically conductive adhesive layer 6, and the transparent electrically conductive layer 4 toward one side in the thickness direction.

That is, the electrically conductive adhesive layer 6 is provided between the conductive layer 5 and the transparent electrically conductive layer 4.

Thus, the adhesive properties between the conductive layer 5 and the transparent electrically conductive layer 4 are excellent.

Among all, when the transparent electrically conductive layer 4 of the transparent electrically conductive film 1 is formed into a pattern by the photo resist, the adhesive properties of the conductive layer 5 with the transparent electrically conductive layer 4 including the metal nanowire are low, so that the transparent electrically conductive layer 4 may be peeled.

Meanwhile, in the transparent electrically conductive film 1, the electrically conductive adhesive layer 6 is provided between the conductive layer 5 and the transparent electrically conductive layer 4, so that the adhesive properties between the conductive layer 5 and the transparent electrically conductive layer 4 are excellent. As a result, when a pattern is formed by the photo resist, peeling of the transparent electrically conductive layer 4 can be suppressed.

In the method for producing the transparent electrically conductive film 1, in the second step, the conductive layer 5, the electrically conductive adhesive layer 6, and the transparent electrically conductive layer 4 are sequentially disposed toward one side in the thickness direction in the frame region 11.

Thus, the transparent electrically conductive film 1 having excellent adhesive properties between the conductive layer 5 and the transparent electrically conductive layer 4 can be obtained.

9. Intermediate

The intermediate 12 is a component that can be used for the method for producing the transparent electrically conductive film 1.

The intermediate 12 sequentially includes the transparent substrate 2, the conductive layer 5, and the electrically conductive adhesive layer 6 toward one side in the thickness direction, or sequentially includes the transparent substrate 2, the transparent electrically conductive layer 4, and the electrically conductive adhesive layer 6 toward one side in the thickness direction.

Among all, as described above, when the frame region 11 sequentially includes the conductive layer 5, the electrically conductive adhesive layer 6, and the transparent electrically conductive layer 4 toward one side in the thickness direction, as shown in FIG. 2C, the intermediate 12 sequentially includes the transparent substrate 2, the conductive layer 5, and the electrically conductive adhesive layer 6 toward one side in the thickness direction.

According to the intermediate 12, the transparent electrically conductive film 1 having excellent adhesive properties between the conductive layer 5 and the transparent electrically conductive layer 4 can be obtained.

10. Modified Examples

In modified examples, the same reference numerals are provided for members and steps corresponding to each of those in one embodiment, and their detailed description is omitted. Each of the modified examples can achieve the same function and effect as that of one embodiment unless otherwise specified. Furthermore, one embodiment and the modified examples can be appropriately used in combination.

In the above-described description, the frame region 11 sequentially includes the conductive layer 5, the electrically conductive adhesive layer 6, and the transparent electrically conductive layer 4 toward one side in the thickness direction. Alternatively, the frame region 11 can also sequentially include the transparent electrically conductive layer 4, the electrically conductive adhesive layer 6, and the conductive layer 5 toward one side in the thickness direction.

In this case, in the second step of the method for producing a transparent electrically conductive film, first, the transparent electrically conductive layer 4 is disposed on the entire one-side surface in the thickness direction of the transparent substrate 2; next, the electrically conductive adhesive layer 6 is disposed on the entire one-side surface in the thickness direction of the transparent electrically conductive layer 4; and next, the transparent electrically conductive layer 4 and the electrically conductive adhesive layer 6 are formed into a pattern, so that the visible region 10 and the frame region 11 are formed. Next, the conductive layer 5 is disposed on the one-side surface in the thickness direction of the frame region 11 (one-side surface in the thickness direction of the electrically conductive adhesive layer 6).

In this case, the intermediate 12 sequentially includes the transparent substrate 2, the transparent electrically conductive layer 4, and the electrically conductive adhesive layer 6 toward one side in the thickness direction.

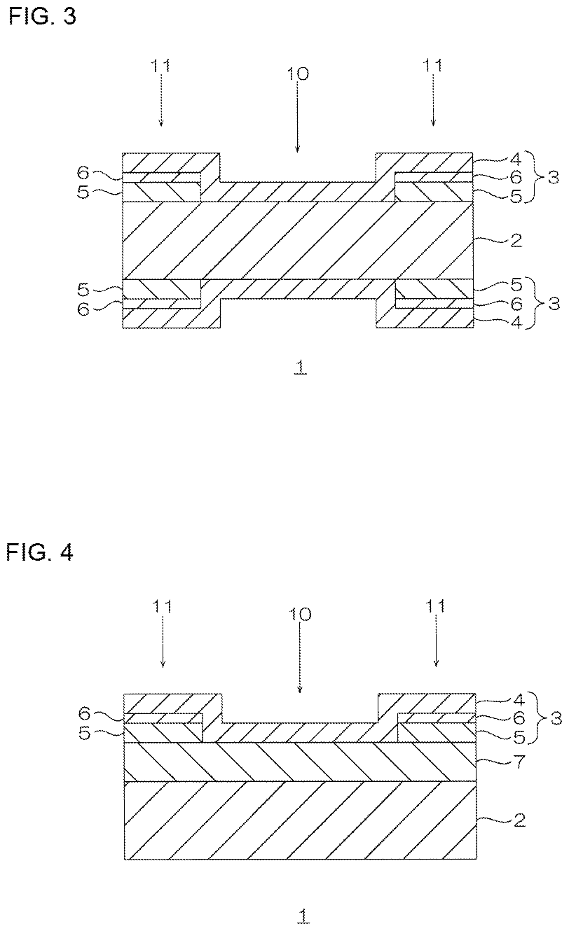

In the above-described description, the electrically conductive layer 3 is disposed on one side in the thickness direction of the transparent substrate 2. Alternatively, as shown in FIG. 3, the electrically conductive layer 3 can be also disposed on both sides (one side in the thickness direction and the other side in the thickness direction) of the transparent substrate 2.

In this case, the transparent electrically conductive film 1 sequentially includes the electrically conductive layer 3, the transparent substrate 2, and the electrically conductive layer 3 toward one side in the thickness direction. To be more specific, the transparent electrically conductive film 1 sequentially includes the transparent electrically conductive layer 4, the transparent substrate 2, and the transparent electrically conductive layer 4 toward one side in the thickness direction in the visible region 10, and sequentially includes the transparent electrically conductive layer 4, the electrically conductive adhesive layer 6, the conductive layer 5, the transparent substrate 2, the conductive layer 5, the electrically conductive adhesive layer 6, and the transparent electrically conductive layer 4 toward one side in the thickness direction in the frame region 11.

When the electrically conductive layer 3 is disposed on both sides of the transparent substrate 2, there are advantages of achieving a reduction in thickness due to use of the transparent substrate 2 in common and improvement of position accuracy of a patterned wire.

In the above-described description, the electrically conductive layer 3 is disposed on the upper surface (one-side surface in the thickness direction) of the transparent substrate 2. Alternatively, a hard coat layer 7 can be also disposed on the upper surface (one-side surface in the thickness direction) of the transparent substrate 2.

In this case, as shown in FIG. 4, the transparent electrically conductive film 1 includes the transparent substrate 2, the hard coat layer 7 that is disposed on the upper surface (one-side surface in the thickness direction) of the transparent substrate 2, and the electrically conductive layer 3 that is disposed on the upper surface (one-side surface in the thickness direction) of the hard coat layer 7.

The hard coat layer 7 is a protective layer for suppressing generation of damage to the transparent substrate 2 when the transparent electrically conductive film 1 is produced. The hard coat layer 7 is also an abrasion-resistance layer for suppressing generation of an abrasion on the transparent electrically conductive layer 4 when the transparent electrically conductive film 1 is laminated.

The hard coat layer 7 is formed from a hard coat composition.

The hard coat composition contains a resin and particles.

Examples of the resin include curable resin and thermoplastic resin (for example, polyolefin resin). Preferably, a curable resin is used.

Examples of the curable resin include active energy ray curable resin that cures by application of an active energy ray (to be specific, ultraviolet ray, electron ray, or the like) and thermosetting resin that cures by heating. Preferably, an active energy ray curable resin is used.

An example of the active energy ray curable resin includes a polymer having a functional group having a polymerizable carbon-carbon double bond in a molecule. Examples of the functional group include vinyl group and (meth)acryloyl group (methacryloyl group and/or acryloyl group).

To be specific, examples of the active energy ray curable resin include (meth)acrylic ultraviolet ray curable resins such as urethane acrylate and epoxy acrylate.

Examples of the curable resin other than the active energy ray curable resin include thermosetting resins such as urethane resin, melamine resin, alkyd resin, siloxane polymer, and organic silane condensate.

These resins can be used alone or in combination of two or more.

Examples of the particles include inorganic particles such as silica particles and zirconia particles and organic particles such as cross-linking acrylic particles.

Each of the particles has an average particle size of, for example, 10 nm or more, and for example, 3000 nm or less, preferably 1000 nm or less, more preferably 100 nm or less, further more preferably 50 nm or less.

The hard coat composition can be obtained by mixing the resin with the particles.

A known additive such as levelling agent, thixotropy agent, and antistatic agent can be also blended into the hard coat composition as needed.

To form the hard coat layer 7, a diluted solution of the hard coat composition is applied to the one-side surface in the thickness direction of the transparent substrate 2 to be then dried. After drying, the hard coat composition cures by application of the ultraviolet ray.

In this manner, the hard coat layer 7 is formed.

In view of abrasion resistance, the hard coat layer 7 has a thickness of, for example, 0.1 μm or more, preferably 0.5 μm or more, more preferably 0.8 μm or more, and for example, 10 μm or less, preferably 2 μm or less. The thickness of the hard coat layer 7 can be, for example, measured by observing a cross section by using the transmission electron microscope.

The electrically conductive layer 3 is formed on the upper surface (one-side surface in the thickness direction) of the hard coat layer 7 in the same manner as the description above.

The hard coat layer 7 can be also disposed on both sides (one side in the thickness direction and the other side in the thickness direction) of the transparent substrate 2.

### EXAMPLES

Next, the present invention is further described based on Examples and Comparative Example shown below. The present invention is however not limited by these Examples and Comparative Example. The specific numerical values in mixing ratio (content ratio), property value, and parameter used in the following description can be replaced with upper limit values (numerical values defined as “or less” or “below”) or lower limit values (numerical values defined as “or more” or “above”) of corresponding numerical values in mixing ratio (content ratio), property value, and parameter described in the above-described “Embodiment of the Invention”.

1. Production of Transparent Electrically Conductive Film for Test

In Examples and Comparative Example below, a transparent electrically conductive film for test was produced as a transparent electrically conductive film for evaluation to be described later.

The transparent electrically conductive film for test was obtained by disposing a transparent electrically conductive layer on the entire one-side surface in the thickness direction of an electrically conductive adhesive layer without forming the conductive layer and the electrically conductive adhesive layer into a pattern (without forming the visible region and the frame region) in the above-described second step.

The result of evaluation (described later) with respect to the transparent electrically conductive film for test can be replaced with the result of evaluation (described later) with respect to the transparent electrically conductive film of the present invention.

### Example 1

As a transparent substrate, a cycloolefin film (thickness of 40 μm, “ZeonorFilm” manufactured by ZEON CORPORATION) was prepared.

A liquid for a hard coat layer containing an ultraviolet ray curable acrylic resin was applied to both surfaces of the transparent substrate to be dried. Thereafter, a curable resin composition cured by application of the ultraviolet ray. In this manner, a hard coat layer having a thickness of 1.0 μm was formed.

Next, a conductive layer was formed on the entire one-side surface in the thickness direction of the hard coat layer on one side in the thickness direction of the hard coat layers that were provided on both surfaces of the transparent substrate.

To be specific, sputtering was carried out by using a copper target by adjusting a set thickness of sputtering output to 200 nm by a DC sputtering method. As vacuum conditions, argon gas was introduced, and an atmospheric pressure was set at 0.3 Pa. In this manner, a conductive layer (copper layer) having a thickness of 200 nm was formed.

Furthermore, an electrically conductive adhesive layer was formed on the entire one-side surface in the thickness direction of the conductive layer.

To be specific, the sputtering was carried out by using a chromium target by adjusting the set thickness of the sputtering output to 5.0 nm by the DC sputtering method. As the vacuum conditions, the argon gas was introduced, and the atmospheric pressure was set at 0.3 Pa. In this manner, an electrically conductive adhesive layer (chromium layer) having a thickness of 5.0 nm was formed.

Then, a transparent electrically conductive layer was formed on the entire one-side surface in the thickness direction of the electrically conductive adhesive layer.

To be specific, a diluted solution of a transparent electrically conductive composition containing 0.15 mass % of silver nanowire (average fiber length of 10 μm, average fiber size of 10 nm), 0.45 mass % of binder resin (cellulose derivative), and 99.4 mass % of aqueous solvent was applied to the electrically conductive adhesive layer to be dried, so that the transparent electrically conductive layer having a thickness of 10 to 80 nm was formed.

In this manner, the transparent electrically conductive film for test sequentially including the hard coat layer, the transparent substrate, the hard coat layer, and the electrically conductive layers (the conductive layer, the electrically conductive adhesive layer, and the transparent electrically conductive layer) toward one side in the thickness direction was obtained.

### Example 2

A transparent electrically conductive film for test was obtained in the same manner as that of Example 1, except that the thickness of the electrically conductive adhesive layer (chromium layer) was changed to 2.5 nm.

### Example 3

A transparent electrically conductive film for test was obtained in the same manner as that of Example 1, except that a SiOₓ (0<x<2) layer as an electrically conductive adhesive layer was provided, and the thickness of the SiOₓ layer was changed to 5 nm.

To be specific, the sputtering was carried out by using a Si target as a target by adjusting the set thickness of the sputtering output to 5.0 nm, thereby forming an electrically conductive adhesive layer.

As the vacuum conditions, argon gas and oxygen gas were introduced with a weight ratio of the argon gas to the oxygen gas of 1 to 1.3, and the atmospheric pressure was set at 0.2 Pa.

### Example 4

A transparent electrically conductive film for test was obtained in the same manner as that of Example 3, except that the thickness of the electrically conductive adhesive layer (SiOₓ layer) was changed to 2.5 nm.

### Example 5

A transparent electrically conductive film for test was obtained in the same manner as that of Example 1, except that a Cu—Ti—Ni layer as an electrically conductive adhesive layer was provided, and the thickness of the Cu—Ti—Ni layer was changed to 5 nm.

To be specific, the sputtering was carried out by using CuTiNi (Cu: 35 mass %, Ti: 3 mass %, and Ni: 62 mass %) as a target by adjusting the set thickness of the sputtering output to 5.0 nm, thereby forming an electrically conductive adhesive layer.

As the vacuum conditions, the argon gas was introduced, and the atmospheric pressure was set at 0.3 Pa.

### Example 6

A transparent electrically conductive film for test was obtained in the same manner as that of Example 5, except that the thickness of the electrically conductive adhesive layer (Cu—Ni—Ti layer) was changed to 2.5 nm.

### Example 7

A transparent electrically conductive film for test was obtained in the same manner as that of Example 1, except that a Ni layer as an electrically conductive adhesive layer was provided, and the thickness of the Ni layer was changed to 5 nm.

To be specific, the sputtering was carried out by using Ni as a target by adjusting the set thickness of the sputtering output to 5.0 nm, thereby forming an electrically conductive adhesive layer.

As the vacuum conditions, the argon gas was introduced, and the atmospheric pressure was set at 0.3 Pa.

### Example 8

A transparent electrically conductive film for test was obtained in the same manner as that of Example 7, except that the thickness of the electrically conductive adhesive layer (Ni layer) was changed to 2.5 nm.

### Example 9

A transparent electrically conductive film for test was obtained in the same manner as that of Example 1, except that an aluminum-doped zinc oxide layer (AZO layer) as an electrically conductive adhesive layer was provided and the thickness of the AZO layer was changed to 5 nm.

To be specific, the sputtering was carried out by using AZO as a target by adjusting the set thickness of the sputtering output to 5.0 nm, thereby forming an electrically conductive adhesive layer.

As the vacuum conditions, the argon gas and the oxygen gas were introduced with a weight ratio of the argon gas to the oxygen gas of 40 to 1, and the atmospheric pressure was set at 0.3 Pa.

### Example 10

A transparent electrically conductive film for test was obtained in the same manner as that of Example 9, except that the thickness of the electrically conductive adhesive layer (AZO layer) was changed to 2.5 nm.

### Comparative Example 1

A transparent electrically conductive film for test was obtained in the same manner as that of Example 1, except that the electrically conductive adhesive layer was not provided.

2. Evaluation

(Adhesive Properties)

A cut of 10 squares×10 squares (100 squares in total) was made in each of the transparent electrically conductive films of Examples and Comparative Examples based on a cross-cut method.

Thereafter, the transparent electrically conductive film for test was immersed in a 1 mass % of KOH aqueous solution at 40° C. for five minutes to be then cleansed with pure water and dried.

Thereafter, of the 100 squares, the number of the square in which the transparent electrically conductive layer was chipped (chipping), the square in which the transparent electrically conductive layer was peeled (peeling), and the square in which the transparent electrically conductive layer was not peeled and chipped (absence of chipping and peeling) was counted.

The results are shown in Table 1.

TABLE 1

| | | | Examples/Comparative Example | | | | | | | | | | |
|---|---|---|---|---|---|---|---|---|---|---|---|---|---|
| | | | | | | | | | | | | | Comparative |
| | | | Ex. 1 | Ex. 2 | Ex. 3 | Ex. 4 | Ex. 5 | Ex. 6 | Ex. 7 | Ex. 8 | Ex. 9 | Ex. 10 | Example 1 |
| Electrically | Thickness (nm) | | 5 | 2.5 | 5 | 2.5 | 5 | 2.5 | 5 | 2.5 | 5 | 2.5 | — |
| Conductive | Material for Electrically | | Cr | Cr | SiOₓ | SiOₓ | Cu—Ni—Ti | Cu—Ni—Ti | Ni | Ni | AZO | AZO | — |
| Adhesive | Conductive Adhesive | | | | | | | | | | | | |
| Layer | Layer | | | | | | | | | | | | |
| Evaluation | Adhesive | Chipping (%) | 15 | 6 | 5 | 4 | 13 | 23 | 31 | 40 | 42 | 19 | 0 |
| | Properties | Peeling (%) | 0 | 0 | 0 | 0 | 0 | 0 | 0 | 0 | 0 | 0 | 100 |
| | | Absence of | 85 | 94 | 95 | 96 | 87 | 77 | 69 | 60 | 58 | 81 | 0 |
| | | Chipping and | | | | | | | | | | | |
| | | Peeling (%) | | | | | | | | | | | |

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### DESCRIPTION OF SYMBOLS

1 Transparent electrically conductive film

2 Transparent substrate

3 Electrically conductive layer

4 Transparent electrically conductive layer

5 Conductive layer

6 Electrically conductive adhesive layer

10 Visible region

11 Frame region

12 Intermediate

1. A transparent electrically conductive film sequentially comprising:
a transparent substrate and an electrically conductive layer toward one side in a thickness direction, wherein
the electrically conductive layer includes a visible region and a frame region disposed in a peripheral edge portion of the visible region;
the visible region includes a transparent electrically conductive layer;
the frame region includes a conductive layer, the transparent electrically conductive layer, and an electrically conductive adhesive layer disposed therebetween for achieving adhesion of the conductive layer to the transparent electrically conductive layer; and
the transparent electrically conductive layer includes a metal nanowire.

2. The transparent electrically conductive film according to claim 1, wherein
the frame region sequentially includes the conductive layer, the electrically conductive adhesive layer, and the transparent electrically conductive layer toward one side in the thickness direction.

3. The transparent electrically conductive film according to claim 1, wherein
the electrically conductive layer is disposed on both sides of the transparent substrate.

4. The transparent electrically conductive film according to claim 1, wherein
the metal nanowire is a silver nanowire.

5. The transparent electrically conductive film according to claim 1, wherein
the conductive layer is a copper layer.

6. The transparent electrically conductive film according to claim 1, wherein
the electrically conductive adhesive layer contains one or more selected from the group consisting of chromium, nickel, silicon oxide, and aluminum-doped zinc oxide.

7. The transparent electrically conductive film according to claim 1 for photo resist or wet etching.

8. A method for producing a transparent electrically conductive film comprising:
a first step of preparing a transparent substrate and
a second step of disposing an electrically conductive layer including a visible region and a frame region disposed in a peripheral edge portion of the visible region on the transparent substrate, wherein
in the second step, a transparent electrically conductive layer is disposed in the visible region, and a conductive layer, the transparent electrically conductive layer, and an electrically conductive adhesive layer disposed therebetween for achieving adhesion of the conductive layer to the transparent electrically conductive layer are disposed in the frame region; and
the transparent electrically conductive layer includes a metal nanowire.

9. An intermediate used for the method for producing a transparent electrically conductive film according to claim 8 sequentially comprising:
the transparent substrate, the conductive layer, and the electrically conductive adhesive layer toward one side in a thickness direction, or
the transparent substrate, the transparent electrically conductive layer, and the electrically conductive adhesive layer toward one side in the thickness direction.
